(19) United States
(12) Patent Application Publication
(10) Pub. No.: US 2025/0386678 A1
(43) Pub. Date: Dec. 18, 2025

(54) DISPLAY APPARATUS AND METHOD OF MANUFACTURING THE SAME

(71) Applicant: Samsung Display Co., Ltd., Yongin-si (KR)

(72) Inventors: Seunghyun Park, Yongin-si (KR); Dahye Kim, Yongin-si (KR); Kangmoon Jo, Yongin-si (KR)

(21) Appl. No.: 19/232,077

(22) Filed: Jun. 9, 2025

(30) Foreign Application Priority Data
Jun. 17, 2024 (KR) 10-2024-0078476

(51) Int. Cl. H10K 59/122; H10K 59/12

(52) U.S. Cl. CPC H10K 59/122; H10K 59/1201

(57) ABSTRACT

A display apparatus is disclosed. The display apparatus may include a substrate, a first pixel electrode, a second pixel electrode, and a third pixel electrode which are apart from each other and are over the substrate, a pixel-defining layer including openings to expose each of central portions of the first pixel electrode, the second pixel electrode, and the third pixel electrode, spacers over the pixel-defining layer, wherein two or more of the spacers are apart from each other if (e.g., when) viewed in a direction perpendicular (e.g., substantially perpendicular) to the substrate, a bank including holes to correspond to the openings of the pixel-defining layer, wherein the bank is over the spacer, a first quantum-dot layer in one or more of the holes of the bank, and a second quantum-dot layer in one or more of the remaining holes of the bank.

### CROSS-REFERENCE TO RELATED APPLICATION

The present application claims priority to and the benefit of Korean Patent Application No. 10-2024-0078476, filed on Jun. 17, 2024, in the Korean Intellectual Property Office, the entire disclosure of which is incorporated herein by reference.

### BACKGROUND

### 1. Field

One or more embodiments of the present disclosure relate to a display apparatus, for example, a display apparatus having a transformed structure to display clear images, a method of manufacturing the display apparatus, and an electronic device.

### 2. Description of the Related Art

A display apparatus has a plurality of pixels. For a full-color display apparatus, a plurality of pixels may emit light of different colors. For this purpose, at least some of pixels in a display apparatus have a color-converting part. For example, at least a portion of light generated from a light-emitting part of some pixels is converted to light of a different color while passing through a corresponding color-converting part and emitted to the outside.

### SUMMARY

However, in display apparatuses that are generally available or generally used, if (e.g., when) implementing high-resolution products, color mixing occurs, and it is desirable to improve or enhance color matching rates.

One or more aspects of embodiments of the present disclosure are directed toward a display apparatus having improved or enhanced color matching rates during a manufacturing process thereof. However, the scope of the present disclosure should not be limited to one or more embodiments and/or examples.

Additional aspects of embodiments will be set forth in part in the description which follows and, in part, will be apparent from the description, or may be learned by practice of the presented embodiments of the disclosure.

According to one or more embodiments, a display apparatus includes a substrate, a first pixel electrode, a second pixel electrode, and a third pixel electrode which are apart from each other and are over the substrate, a pixel-defining layer including openings to expose each of central portions of the first pixel electrode, the second pixel electrode, and the third pixel electrode, wherein the pixel-defining layer is to cover an edge of each of the first pixel electrode, the second pixel electrode, and the third pixel electrode, spacers over the pixel-defining layer, wherein two or more of the spacers are apart from each other if (e.g., when) viewed in a direction perpendicular (e.g., substantially perpendicular) to the substrate, a bank including holes to correspond to the openings of the pixel-defining layer, wherein the bank is over the spacers, a first quantum-dot layer in one or more of the holes of the bank, and a second quantum-dot layer in one or more of the remaining holes of the bank.

If (e.g., when) viewed in the direction perpendicular (e.g., substantially perpendicular) to the substrate, each of the openings of the pixel-defining layer may have a polygonal shape (e.g., a substantially polygonal shape).

If (e.g., when) viewed in the direction perpendicular (e.g., substantially perpendicular) to the substrate, the spacers may be to surround the openings of the pixel-defining layer.

The spacers may include first spacers to surround a set of the first pixel electrode, the second pixel electrode, and the third pixel electrode if (e.g., when) viewed in the direction perpendicular (e.g., substantially perpendicular) to the substrate, and second spacers between the first pixel electrode and the second pixel electrode, between the second pixel electrode and the third pixel electrode, and between the third pixel electrode and the first pixel electrode if (e.g., when) viewed in the direction perpendicular (e.g., substantially perpendicular) to the substrate.

The second spacers may be integrally provided as a single body.

The first spacers may be apart from each other.

The first spacers and the second spacers may be apart from each other.

An angle between adjacent second spacers among the second spacers may be about 90° or greater.

At least one selected from among angles between each of the second spacers and an adjacent spacer among the first spacers may be about 90° or smaller.

A height of the spacers may be greater than a height of the pixel-defining layer.

An angle between a lateral side surface of the spacers and an upper surface of the pixel-defining layer may be greater than an angle between a lower surface of the pixel-defining layer and an inner side surface of the openings.

The spacers may include a black dye.

According to one or more embodiments, a method of manufacturing a display apparatus includes providing a first pixel electrode, a second pixel electrode, and a third pixel electrode which are apart from each other and are over a substrate, providing a pixel-defining layer including openings to expose each of central portions of the first pixel electrode, the second pixel electrode, and the third pixel electrode, wherein the pixel-defining layer is to cover an edge of each of the first pixel electrode, the second pixel electrode, and the third pixel electrode, providing spacers over the pixel-defining layer, wherein two or more of the spacers are apart from each other if (e.g., when) viewed in a direction perpendicular (e.g., substantially perpendicular) to the substrate, providing a bank including holes to correspond to the openings of the pixel-defining layer, wherein the bank is over the spacer, providing a first quantum-dot layer in one or more of the holes of the bank, and providing a second quantum-dot layer in one or more of the remaining holes of the bank.

The providing of the pixel-defining layer may include, if (e.g., when) viewed in the direction perpendicular (e.g., substantially perpendicular) to the substrate, providing the pixel-defining layer in which each of the openings has a polygonal shape (e.g., a substantially polygonal shape).

The providing of the spacers may include, if (e.g., when) viewed in the direction perpendicular (e.g., substantially perpendicular) to the substrate, providing the spacers to surround the openings of the pixel-defining layer.

The providing of the spacers may include providing first spacers to surround a set of the first pixel electrode, the second pixel electrode, and the third pixel electrode if (e.g., when) viewed in the direction perpendicular (e.g., substantially perpendicular) to the substrate, and providing second spacers between the first pixel electrode and the second pixel electrode, between the second pixel electrode and the third pixel electrode, and between the third pixel electrode and the first pixel electrode if (e.g., when) viewed in the direction perpendicular (e.g., substantially perpendicular) to the substrate.

The providing of the second spacers may include providing second spacers integrally as a single body.

The providing of the second spacers may include providing first spacers apart from each other.

The providing of the second spacers may include providing second spacers in which an angle between adjacent spacers among the second spacers is about 90° or greater.

The providing of the spacers may include providing spacers in which at least one selected from among angles between each of the second spacers and an adjacent spacer among the first spacers is about 90° or smaller.

According to one or more embodiments, an electronic device includes the display apparatus as described in one or more embodiments.

The electronic device may be a smartphone, a television, a monitor, a tablet, an electric vehicle, a mobile phone, a tablet personal computer (PC), a mobile communication terminal, an electronic notebook, an electronic book, a portable multimedia player (PMP), a navigation device, an ultra-mobile PC (UMPC), a laptop computer, a billboard, an Internet of Things (IoT) device, a smartwatch, a watch phone, and/or a head-mounted display (HMD).

The above and other aspects and features of certain embodiments of the present disclosure will become more apparent and more readily appreciated from the following detailed description of the embodiments, the accompanying drawings, and the appended claims and equivalents thereof.

### BRIEF DESCRIPTION OF THE DRAWINGS

The above and other aspects and features of certain embodiments of the present disclosure will be more apparent from the following description taken in conjunction with the accompanying drawings, in which:

FIG. 1 is a schematic plan view of a display apparatus according to one or more embodiments;

FIG. 2 is a schematic plan view of a portion A of the display apparatus according to one or more embodiments;

FIG. 3 is a schematic cross-sectional view of the display apparatus of FIG. 2 according to one or more embodiments, taken along line I-I′ of FIG. 2;

FIG. 4A is a schematic plan view of a portion of a display apparatus according to one or more embodiments, and FIGS. 4B-4E each is an enlarged plan view of a portion of the plan view of FIG. 4A according to one or more embodiments;

FIGS. 5A-5C each is a graph illustrating experimental results to describe an effect according to one or more embodiments; and

FIG. 6 is a schematic cross-sectional view of a portion of a display apparatus according to one or more embodiments.

### DETAILED DESCRIPTION

Reference will be made in more detail to one or more embodiments, examples of which are illustrated in the accompanying drawings, wherein like reference numerals refer to like elements throughout. In this regard, the subject matter of the present disclosure may be embodied in different forms and should not be construed as being limited to one or more embodiments set forth herein. Rather, these embodiments are provided as examples, by referring to the figures, to explain the aspects and features of the present disclosure to those skilled in the art.

As used herein, the term “and/or” includes any and all combinations of one or more of the associated listed items. Throughout the present disclosure, the expression “at least one of a, b, or c” or “at least one selected from among a, b, or c” indicates only a, only b, only c, both a and b, both a and c, both b and c, all of a, b, and c, or variations thereof.

As the present disclosure allows for one or more suitable changes and embodiments, certain embodiments will be illustrated in the accompanying drawings and described in more detail in the written description. The aspects, effects, and/or embodiments of the present disclosure and methods for achieving them will be clarified with reference to one or more embodiments and the accompanying drawings described below in more detail. However, the disclosure is not limited to the disclosed embodiments and may be embodied in one or more suitable forms.

While terms, such as “first,” “second,” and/or the like, may be used to describe one or more elements, such elements must not be limited to the foregoing terms. The foregoing terms are used to distinguish one element from another.

The singular forms “a,” “an,” and “the” as used herein are intended to include the plural forms as well unless the context clearly indicates otherwise.

It will be understood that the terms “include,” “have,” “including,” and/or “having” as used herein specify the presence of stated features or elements but do not preclude the addition of one or more other features or elements.

In the present disclosure, “A and/or B” refers to “A or B” or “A and B.” In the present disclosure, “at least one of A and B” or “at least one selected from among A and B” refers to “A or B” or “A and B.”

As used herein, if (e.g., when) one or more elements, such as a layer, a region, a plate, and/or the like, are “on” another element, not only the elements may be “directly on” the other element, but another element may be therebetween. In contrast, if (e.g., when) an element is referred to as being “directly on” another element, there are no intervening elements present.

In one or more embodiments, sizes of elements in the drawings may be exaggerated or reduced for convenience of illustration. As an example, the size and thickness of each element illustrated in the drawings may be arbitrarily represented for convenience of description, and thus, embodiments of the present disclosure are not necessarily limited thereto.

An x direction, a y direction, and a z direction are not limited to directions along three axes of the rectangular coordinate system and may be interpreted in a broader sense. For example, the x direction, the y direction, and the z direction may be perpendicular (e.g., substantially perpendicular) to one another, or may represent different orientations that are not perpendicular (e.g., not substantially perpendicular) to one another.

Hereinafter, one or more embodiments will be described with reference to the accompanying drawings, wherein like reference numerals refer to like elements throughout, and a repeated description thereof may be omitted.

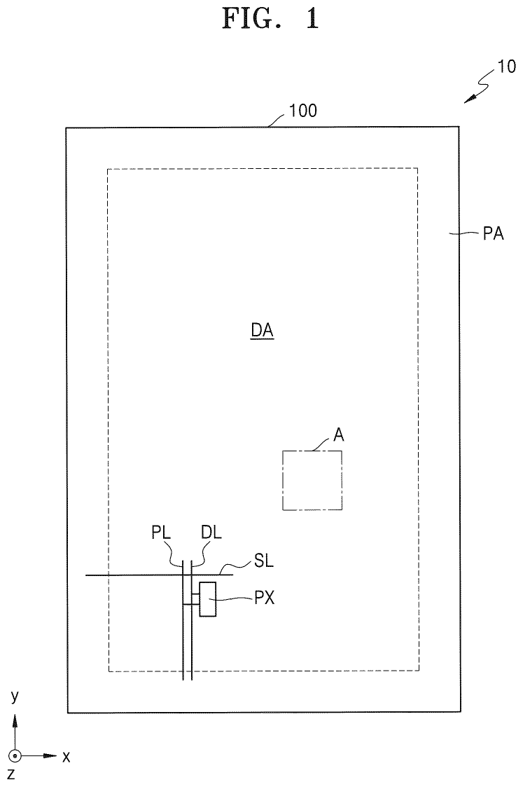

FIG. 1 is a schematic plan view of a display apparatus according to one or more embodiments.

In FIG. 1, the display apparatus according to one or more embodiments may include a display panel 10. As long as a display apparatus includes the display panel 10, any suitable display apparatus may be utilized. As an example, the display apparatus may include one or more suitable apparatuses, such as smartphones, tablet computers, laptop computers, televisions, advertisement boards, and/or the like.

The display panel 10 may include a display area DA and a peripheral area PA outside the display area DA. In FIG. 1, the display area DA may have a rectangular (e.g., substantially rectangular) shape. However, embodiments of the present disclosure are not limited thereto. The display area DA may have other shapes, for example, circular (e.g., substantially circular) shapes, elliptical (e.g., substantially elliptical) shapes, polygonal (e.g., substantially polygonal) shapes, or shapes of specific figures.

The display area DA may be a region in which images are displayed, and a plurality of pixels PX may be in the display area DA. Each pixel PX may include a display element, such as an organic light-emitting diode (OLED). Each pixel PX may be to emit, for example, red, green, or blue light. The pixel PX may be connected (e.g., electrically connected) to a pixel circuit including a thin-film transistor TFT, a storage capacitor, and/or the like. The pixel circuit may be connected (e.g., electrically connected) to a scan line SL, a data line DL, and a driving voltage line PL, wherein the scan line SL may be to transfer scan signals, the data line DL may be to cross the scan line SL and transfer data signals, and the driving voltage line PL may be to supply a driving voltage. The scan line SL may extend in an x direction, and the data line DL and the driving voltage line PL may extend in a y direction.

The pixel PX may be to emit light of a brightness to correspond to an electrical signal from the pixel circuit electrically connected thereto. The display area DA may be to display preset images by using light emitted from the pixel PX. For example, as described in one or more embodiments, the pixel PX may be defined as a region that is to emit one selected from among red, green, and blue light.

The peripheral area PA may be a region in which pixels PX are not provided and may be a region that is not to display images. A power supply line to drive the pixel PX and/or the like may be in the peripheral area PA. In one or more embodiments, a printed circuit board including a driving circuit portion and/or a terminal portion to which a driver integrated circuit (IC) is connected (e.g., electrically connected) may be in the peripheral area PA.

For example, because the display panel 10 includes a second substrate 100, it may be understood that the second substrate 100 includes the display area DA and the peripheral area PA.

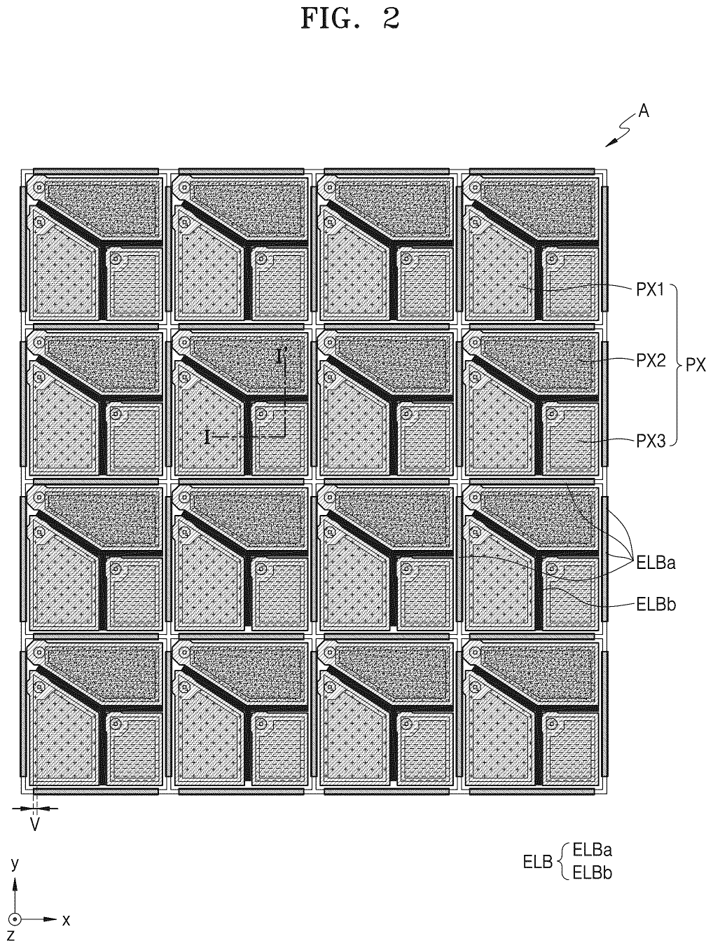

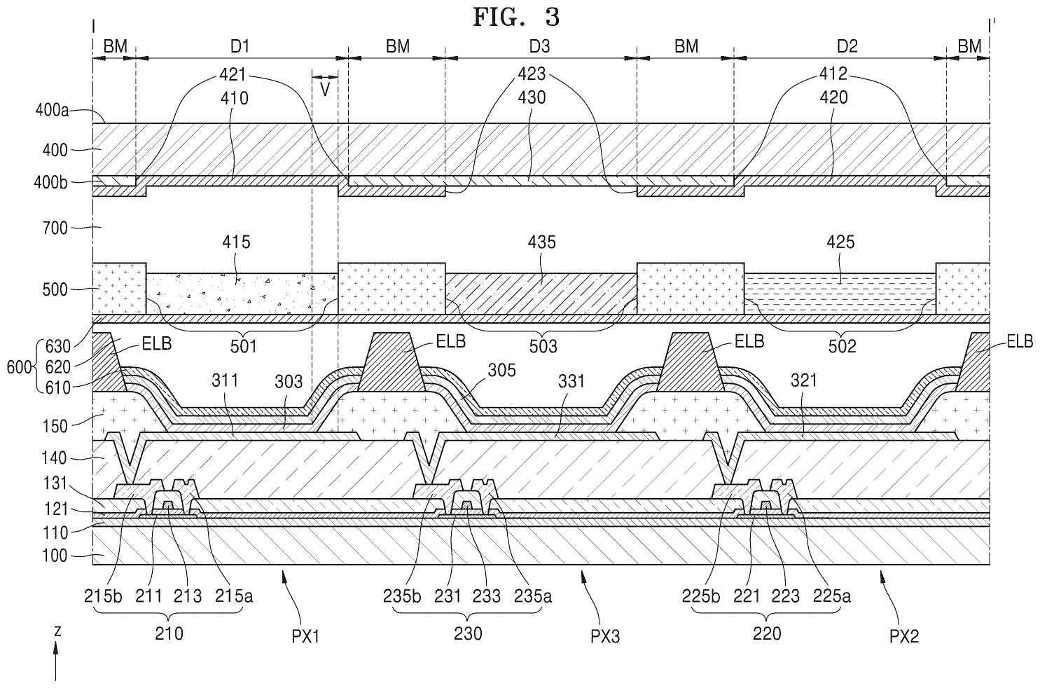

FIG. 2 is a schematic plan view of a portion A of the display apparatus according to one or more embodiments, and FIG. 3 is a schematic cross-sectional view of the display apparatus of FIG. 2 according to one or more embodiments, taken along line I-I′ of FIG. 2.

Referring to FIG. 2, the display apparatus may include a plurality of pixels PX. The pixels PX may include a first pixel PX1, a second pixel PX2, and a third pixel PX3 to emit light of different colors. The first pixel PX1 may be a pixel to emit red light, the second pixel PX2 may be a pixel to emit green light, and the third pixel PX3 may be a pixel to emit blue light.

In one or more embodiments, the first pixel PX1, the second pixel PX2, and the third pixel PX3 may each have a polygonal (e.g., substantially polygonal) shape if (e.g., when) viewed in a direction (a z axis direction) perpendicular (e.g., substantially perpendicular) to the second substrate 100. In FIG. 2, each of the first pixel PX1, the second pixel PX2, and the third pixel PX3 may have a polygonal (e.g., a substantially polygonal) shape, for example, a polygonal (e.g., a substantially polygonal) shape in which there is an angle between portions of edge if (e.g., when) viewed in the direction (the z axis direction) perpendicular (e.g., substantially perpendicular) to the second substrate 100. For example, a portion of each of the first pixel electrode 311 of the first pixel PX1, the second pixel electrode 321 of the second pixel PX2, and the third pixel electrode 331 of the third pixel PX3 exposed by the pixel-defining layer 150 may have a polygonal (e.g., a substantially polygonal) shape in which there is an angle between portions of an edge.

However, embodiments of the present disclosure are not limited thereto. As an example, each of the first pixel PX1, the second pixel PX2, and the third pixel PX3, for example, a portion of each of the first pixel electrode 311 of the first pixel PX1, the second pixel electrode 321 of the second pixel PX2, and the third pixel electrode 331 of the third pixel PX3 exposed by the pixel-defining layer 150, may have a circular (e.g., substantially circular) shape or an elliptical (e.g., substantially elliptical) shape other than a polygonal (e.g., a substantially polygonal) shape if (e.g., when) viewed in the direction (the z axis direction) perpendicular (e.g., substantially perpendicular) to the second substrate 100. In one or more embodiments, each of the first pixel PX1, the second pixel PX2, and the third pixel PX3, for example, a portion of each of the first pixel electrode 311 of the first pixel PX1, the second pixel electrode 321 of the second pixel PX2, and the third pixel electrode 331 of the third pixel PX3 exposed by the pixel-defining layer 150, may have a shape in which a quadrangle is chamfered, for example, an octagonal (e.g., substantially octagonal) shape. In one or more embodiments, the degree of chamfering of the edge may be substantially different. For example, all of the lengths of the edges of the octagon (e.g., the substantially octagon) may not be substantially the same.

The sizes, for example, the areas of the first pixel PX1, the second pixel PX2, and the third pixel PX3, may be substantially different from each other. As an example, the area of the second pixel PX2 may be greater than the area of the first pixel PX1 and/or the area of the third pixel PX3. In one or more embodiments, the area of the first pixel PX1 may be greater than the area of the third pixel PX3.

The first pixel PX1 may include the first pixel electrode 311, the second pixel PX2 may include the second pixel electrode 321, and the third pixel PX3 may include the third pixel electrode 331. Referring to FIG. 3, the pixel-defining layer 150 may cover an edge of each of the first pixel electrode 311, the second pixel electrode 321, and the third pixel electrode 331. For example, the pixel-defining layer 150 may have an opening to expose the central portion of the first pixel electrode 311, an opening to expose the central portion of the second pixel electrode 321, and an opening to expose the central portion of the third pixel electrode 331.

In one or more embodiments, if (e.g., when) viewed in the direction (the z axis direction) perpendicular (e.g., substantially perpendicular) to the second substrate 100, the first pixel PX1 and/or the second pixel PX2 may have a trapezoidal (e.g., substantially trapezoidal) shape, and the third pixel PX3 may have a rectangular (e.g., substantially rectangular) shape. One side of the first pixel PX1 may contact one side of the second pixel PX2, and another side of the first pixel PX1 may contact one side of the third pixel PX3. Another side of the second pixel PX2 that does not contact the first pixel PX1 may contact another side of the third pixel PX3 that does not contact the first pixel PX1 among the sides of the third pixel PX3. In one or more embodiments, if (e.g., when) viewed in the direction (the z axis direction) perpendicular (e.g., substantially perpendicular) to the second substrate 100, the shapes of the area of the first pixel PX1, the area of the second pixel PX2, and the area of the third pixel PX3 may be combined to provide an overall rectangular (e.g., substantially rectangular) or square (e.g., substantially square) shape. According to one or more embodiments, in the display area DA, a set of pixels in a rectangular (e.g., substantially rectangular) or square (e.g., substantially square) shape, the shapes of which are a combination of the area of the first pixel PX1, the area of the second pixel PX2, and the area of the third pixel PX3, may be repeatedly in a row to extend in a first direction (an x axis direction) and/or a column to extend in a second direction (a y axis direction) crossing the first direction.

In one or more embodiments, the first pixel PX1, the second pixel PX2, and the third pixel PX3 may be in a PenTile® (e.g., substantially PenTile®) arrangement, a stripe (e.g., substantially stripe) arrangement, a mosaic (e.g., substantially mosaic) arrangement, or an S-stripe (e.g., substantially S-stripe) arrangement.

Referring to FIG. 3, the display apparatus according to one or more embodiments may include the second substrate 100, which is a lower substrate, the first pixel electrode 311, the second pixel electrode 321, and the third pixel electrode 331 over the second substrate 100, the pixel-defining layer 150, and a first substrate 400, which is an upper substrate.

The second substrate 100 may include glass, metal, and/or a polymer resin. The second substrate 100 may include a polymer resin, such as polyethersulfone, polyacrylate, polyetherimide, polyethylene naphthalate, polyethylene terephthalate, polyphenylene sulfide, polyarylate, polyimide, polycarbonate, and/or cellulose acetate propionate. The second substrate 100 may have a multi-layered structure including two layers each including the polymer resin and/or a barrier layer including an inorganic material (such as silicon oxide, silicon nitride, and/or silicon oxynitride) therebetween. However, one or more suitable modifications may be made.

The first pixel electrode 311, the second pixel electrode 321, and the third pixel electrode 331 may be over the second substrate 100. Besides the first pixel electrode 311, the second pixel electrode 321, and the third pixel electrode 331, a first thin-film transistor 210, a second thin-film transistor 220, and a third thin-film transistor 230, each of which is electrically connected to a corresponding one selected from among the first pixel electrode 311, the second pixel electrode 321, and the third pixel electrode 331, may be over the second substrate 100. For example, in FIG. 3, the first pixel electrode 311 may be electrically connected to the first thin-film transistor 210, the second pixel electrode 321 may be electrically connected to the second thin-film transistor 220, and the third pixel electrode 331 may be electrically connected to the third thin-film transistor 230. The first pixel electrode 311, the second pixel electrode 321, and the third pixel electrode 331 may be on a planarization layer 140, as described in one or more embodiments, that is over the second substrate 100.

The first thin-film transistor 210 may include a first semiconductor layer 211, a first gate electrode 213, a first source electrode 215a, and a first drain electrode 215b, wherein the first semiconductor layer 211 may include amorphous (e.g., non-crystalline) silicon, polycrystalline silicon, an organic semiconductor material, and/or an oxide semiconductor material. The first gate electrode 213 may include one or more suitable conductive (e.g., electrically conductive) materials and have one or more suitable layered structures, and include, for example, a molybdenum (Mo) layer and/or an aluminum (Al) layer. In one or more embodiments, the first gate electrode 213 may have a layered structure of Mo/Al/Mo. In one or more embodiments, the first gate electrode 213 may include a titanium nitride (TiNₓ, wherein 0<X≤2) layer, an aluminum (Al) layer, and/or a titanium (Ti) layer. The first source electrode 215a and the first drain electrode 215b may also include one or more suitable conductive (e.g., electrically conductive) materials and one or more suitable layered structures, and may include, for example, a titanium (Ti) layer, an aluminum (Al) layer, and/or a copper (Cu) layer. In one or more embodiments, the first source electrode 215a and the first drain electrode 215b may each have a layered structure of Ti/Al/Ti.

To provide insulation (e.g., electrical insulation) between the first semiconductor layer 211 and the first gate electrode 213, a gate insulating layer 121 may be between the first semiconductor layer 211 and the first gate electrode 213, wherein the gate insulating layer 121 may include an inorganic material, such as silicon oxide, silicon nitride, and/or silicon oxynitride. In one or more embodiments, an interlayer insulating layer 131 may be on the first gate electrode 213, wherein the interlayer insulating layer 131 may include an inorganic material, such as silicon oxide, silicon nitride, and/or silicon oxynitride. The first source electrode 215a and the first drain electrode 215b may be on the interlayer insulating layer 131. The insulating (e.g., electrically insulating) layer including the inorganic material may be provided by deposition methods, (e.g., chemical vapor deposition (CVD) and/or atomic layer deposition (ALD)). This illustration may also be applicable to one or more embodiments of the present disclosure and modifications thereof.

A buffer layer 110 may be between the first thin-film transistor 210 having the foregoing structure and the second substrate 100, wherein the buffer layer 110 may include an inorganic material, such as silicon oxide, silicon nitride, and/or silicon oxynitride. The buffer layer 110 may be to increase or enhance flatness of the upper surface of the second substrate 100 and/or to prevent or reduce undesirable impurities (e.g., a degree or occurrence of undesirable impurities) from the second substrate 100 from penetrating the first semiconductor layer 211 of the first thin-film transistor 210.

The second thin-film transistor 220 in the second pixel PX2 may include a second semiconductor layer 221, a second gate electrode 223, a second source electrode 225a, and a second drain electrode 225b. The third thin-film transistor 230 in the third pixel PX3 may include a third semiconductor layer 231, a third gate electrode 233, a third source electrode 235a, and a third drain electrode 235b. Because the structure of the second thin-film transistor 220 and the structure of the third thin-film transistor 230 are substantially the same as or similar to the structure of the first thin-film transistor 210 in the first pixel PX1, repeated descriptions thereof may be omitted.

The planarization layer 140 may be on the first thin-film transistor 210. As an example, in FIG. 3, if (e.g., when) an organic light-emitting element including the first pixel electrode 311 is over the first thin-film transistor 210, the planarization layer 140 may planarize (e.g., generally planarize) an upper portion of a protective layer to cover the first thin-film transistor 210. The planarization layer 140 may include, for example, acryl, benzocyclobutene (BCB), and/or hexamethyldisiloxane (HMDSO). Although it is illustrated in FIG. 3 that the planarization layer 140 is a single layer, the planarization layer 140 may have a multi-layered structure. However, one or more suitable modifications may be made.

An organic light-emitting element may be in the first pixel PX1, wherein the organic light-emitting element may include the first pixel electrode 311, an opposite electrode 305, and an intermediate layer 303 therebetween, wherein the intermediate layer 303 may include an emission layer. In FIG. 3, the first pixel electrode 311 may be electrically connected to the first thin-film transistor 210 by being in contact with one selected from among the first source electrode 215a and the first drain electrode 215b through a contact hole in the planarization layer 140 and/or the like. The first pixel electrode 311 may include a light-transmissive conductive (e.g., electrically conductive) layer and a reflective layer (e.g., a layer to enhance its ability to reflect light or other forms of electromagnetic radiation), wherein the light-transmissive conductive (e.g., electrically conductive) layer may include a light-transmissive conductive (e.g., electrically conductive) oxide, such as indium tin oxide (ITO), indium oxide (e.g., In₂O₃), and/or indium zinc oxide (IZO), and the reflective layer may include metal, such as aluminum (Al) and/or silver (Ag). As an example, the first pixel electrode 311 may have a three-layered structure of ITO/Ag/ITO.

An organic light-emitting element may be in the second pixel PX2, wherein the organic light-emitting element may include the second pixel electrode 321, the opposite electrode 305, and the intermediate layer 303 therebetween, wherein the intermediate layer 303 may include the emission layer. An organic light-emitting element may be in the third pixel PX3, wherein the organic light-emitting element may include the third pixel electrode 331, the opposite electrode 305, and the intermediate layer 303 therebetween, wherein the intermediate layer 303 may include the emission layer. The second pixel electrode 321 may be electrically connected to the second thin-film transistor 220 by being in contact with one selected from among the second source electrode 225a and the second drain electrode 225b through a contact hole in the planarization layer 140 and/or the like. The third pixel electrode 331 may be electrically connected to the third thin-film transistor 230 by being in contact with one selected from among the third source electrode 235a and the third drain electrode 235b through a contact hole in the planarization layer 140 and/or the like. The description of the first pixel electrode 311 may be applicable to the second pixel electrode 321 and/or the third pixel electrode 331.

In one or more embodiments, the intermediate layer 303 including the emission layer may also be on the second pixel electrode 321 of the second pixel PX2 and the third pixel electrode 331 of the third pixel PX3 as well as the first pixel electrode 311 of the first pixel PX1. The intermediate layer 303 may have an integrally provided single body shape over the first pixel electrode 311, the second pixel electrode 321, and the third pixel electrode 331. If (e.g., when) desired or needed, the intermediate layer 303 may be patterned on the first pixel electrode 311, the second pixel electrode 321, and the third pixel electrode 331. The intermediate layer 303 may include a hole injection layer, a hole transport layer, an electronic transport layer, and/or the like in addition to the emission layer. One or more of the layers included in the intermediate layer 303 may have an integrally provided single body shape over the first pixel electrode 311 to third pixel electrode 331, and one or more other layers may be patterned to be over the first pixel electrode 311, the second pixel electrode 321, and the third pixel electrode 331.

The opposite electrode 305 on the intermediate layer 303 may also have an integrally provided single body shape over the first pixel electrode 311 to third pixel electrode 331. The opposite electrode 305 may include a light-transmissive conductive (e.g., electrically conductive) layer including ITO, indium oxide (e.g., In₂O₃), and/or IZO, and/or include a semi-transmissive layer including metal, such as aluminum (Al), lithium (Li), magnesium (Mg), ytterbium (Yb), and/or silver (Ag). As an example, the opposite electrode 330 may be a semi-transmissive layer including MgAg, AgYb, Yb/MgAg, and/or Li/MgAg.

The pixel-defining layer 150 may be on the planarization layer 140. The pixel-defining layer 150 may include openings to correspond to each of the pixels PX. For example, the pixel-defining layer 150 may cover the edge of each of the first pixel electrode 311, the second pixel electrode 321, and the third pixel electrode 331, and may include an opening that is to expose the central portion of the first pixel electrode 311, an opening that is to expose the central portion of the second pixel electrode 321, and an opening that is to expose the central portion of the third pixel electrode 331. In one or more embodiments, the pixel-defining layer 150 may define the pixels. In one or more embodiments, in FIG. 3, the pixel-defining layer 150 may prevent or reduce arcs and/or the like from occurring at the edges of the first pixel electrode 311, the second pixel electrode 321, and the third pixel electrode 331 by increasing a distance between the opposite electrode 305 and the edge of each of the first pixel electrode 311, the second pixel electrode 321, and the third pixel electrode 331. The pixel-defining layer 150 may include an organic material, such as polyimide and/or HMDSO.

The emission layer of the intermediate layer 303 may be to emit light having a wavelength in a first wavelength band. The first wavelength band may be, for example, in a range from about 450 nm to about 495 nm.

The first substrate 400 may be over the second substrate 100 such that the first pixel electrode 311, the second pixel electrode 321, and the third pixel electrode 331 are between the first substrate 400 and the second substrate 100. The first substrate 400 may include glass, metal, and/or a polymer resin. The first substrate 400 may include a polymer resin, such as polyethersulfone, polyacrylate, polyetherimide, polyethylene naphthalate, polyethylene terephthalate, polyphenylene sulfide, polyarylate, polyimide, polycarbonate, and/or cellulose acetate propionate. The first substrate 400 may have a multi-layered structure including two layers each including the polymer resin, and/or a barrier layer including an inorganic material (such as silicon oxide, silicon nitride, and/or silicon oxynitride) therebetween. However, one or more suitable modifications may be made. The first substrate 400 may be flexible (e.g., substantially flexible) and/or bendable (e.g., substantially bendable).

A bank 500 may be on a lower surface 400b of the first substrate 400 in a direction (a-z direction) to the second substrate 100. For example, the bank 500 may be between the first substrate 400 and the second substrate 100. The bank 500 may include a first hole 501, a second hole 502, and a third hole 503.

An encapsulation layer 600 may include an organic encapsulation layer 620, a first inorganic encapsulation layer 610, and a second inorganic encapsulation layer 630. The first inorganic encapsulation layer 610 may be on the opposite electrode 305, the organic encapsulation layer 620 may be on the first inorganic encapsulation layer 610, and the second inorganic encapsulation layer 630 may be on the organic encapsulation layer 620. The organic encapsulation layer 620 may be filled with a filler between the bank 500 and the second substrate 100. As an example, in the display apparatus illustrated in FIG. 3, the filler may fill a space between the second inorganic encapsulation layer 630 and the first inorganic encapsulation layer 610. The filler may include a light-transmissive (e.g., substantially light-transmissive) material. As an example, the filler may include an acryl-based resin and/or an epoxy-based resin.

The bank 500 may be on the second inorganic encapsulation layer 630. The bank 500 may include the first hole 501, the second hole 502, and the third hole 503. The first hole 501 of the bank 500 may be to correspond to an opening of the pixel-defining layer 150 to expose the first pixel electrode 311, the second hole 502 of the bank 500 may be to correspond to an opening of the pixel-defining layer 150 to expose the second pixel electrode 321, and the third hole 503 of the bank 500 may be to correspond to an opening of the pixel-defining layer 150 to expose the third pixel electrode 331. For example, if (e.g., when) viewed in a direction (a z axis direction) perpendicular (e.g., substantially perpendicular) to an upper surface 400a of the first substrate 400, the first hole 501 of the bank 500 may be to overlap the opening of the pixel-defining layer 150 to expose the first pixel electrode 311, the second hole 502 of the bank 500 may be to overlap the opening of the pixel-defining layer 150 to expose the second pixel electrode 321, and the third hole 503 of the bank 500 may be to overlap the opening of the pixel-defining layer 150 to expose the third pixel electrode 331. In one or more embodiments, if (e.g., when) viewed in the direction (the z axis direction) perpendicular (e.g., substantially perpendicular) to the upper surface 400a of the first substrate 400, the shape of the edge of each of the first hole 501, the second hole 502, and the third hole 503 of the bank 500 may be substantially the same as or similar to the shape of the edge of corresponding one among the openings of the pixel-defining layer 150. In one or more embodiments, the first hole 501 of the bank 500 may be to correspond to the first pixel electrode 311, the second hole 502 of the bank 500 may be to correspond to the second pixel electrode 321, and the third hole 503 of the bank 500 may be to correspond to the third pixel electrode 331.

The bank 500 may include one or more suitable materials and include an inorganic material, such as silicon oxide, silicon nitride, and/or silicon oxynitride. If (e.g., when) desired or needed, the bank 500 may include a photoresist material. By utilizing such materials, the bank 500 may be relatively easily provided by processes, such as exposure and developing processes.

A first quantum-dot layer 415 may be inside the first hole 501 of the bank 500. If (e.g., when) viewed in the direction (the z-axis direction) perpendicular (e.g., substantially perpendicular) to the upper surface 400a of the first substrate 400, the first quantum-dot layer 415 may be to overlap the first pixel electrode 311. The first quantum-dot layer 415 may be to convert light in the first wavelength band that passes through the first quantum-dot layer 415 into light in a second wavelength band. The second wavelength band may be, for example, in a range from about 630 nm to about 780 nm. However, embodiments of the present disclosure are not limited thereto, and the wavelength band to which a wavelength, for example, a target the first quantum-dot layer 415 converts, belongs, and/or the wavelength band to which a wavelength after the conversion belongs, may be modified to be substantially different.

The first quantum-dot layer 415 may have an arrangement in which quantum dots are dispersed. In one or more embodiments, quantum dots denote crystals of a semiconductor compound and may include any suitable material that may emit light in one or more wavelength bands depending on the size of the crystals. A diameter of the quantum dots may be, for example, about 1 nm to about 10 nm.

Quantum dots may be synthesized by a wet chemical process, a metal organic chemical vapor deposition process, a molecular beam epitaxy process, and/or a substantially similar process. A wet chemical process is a method of mixing an organic solvent with a precursor material and then growing quantum dot crystals. In a wet chemical process, if (e.g., when) the crystal grows, the organic solvent naturally acts as a dispersant coordinated on the surface of the quantum dot crystal and controls the growth of the crystal. In one or more embodiments, the wet chemical process is relatively easier than vapor deposition, such as metal organic chemical vapor deposition (MOCVD) and/or molecular beam epitaxy (MBE). In one or more embodiments, the wet chemical process may be to control the growth of the quantum dots at low costs.

The quantum dot may include one selected from among a Group III-VI semiconductor compound, a Group II-VI semiconductor compound, a Group III-V semiconductor compound, a Group I-III-VI semiconductor compound, a Group IV-VI semiconductor compound, a Group IV element or compound, or any suitable combination thereof.

Examples of a Group III-VI semiconductor compound may include a two-element compound including In₂S₃, a three-element compound including AgInS, AgInS₂, CuInS, and/or any suitable combination thereof.

Examples of a Group II-VI semiconductor compound may include one selected from among a two-element compound including CdS, CdSe, CdTe, ZnS, ZnSe, ZnTe, ZnO, HgS, HgSe, HgTe, MgSe, and/or MgS, a three-element compound including CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, and/or MgZnS, and a four-element compound including CdZnSeS, CdZnSeTe, CdZnSTe, CdHgSeS, CdHgSeTe, CdHgSTe, HgZnSeS, HgZnSeTe, and/or HgZnSTe, and any suitable combination thereof.

Examples of a Group III-V semiconductor compound may include one selected from among a two-element compound including GaN, GaP, GaAs, GaSb, AlN, AIP, AIAs, AlSb, InN, InP, InAs, and/or InSb, a three-element compound including GaNP, GaNAs, GaNSb, GaPAs, GaPSb, AlNP, AlNAs, AlNSb, AlPAs, AlPSb, InGaP, InNP, InAlP, InNAs, InNSb, InPAs, InPSb, and/or GaAlNP, and a four-element compound including GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, and/or InAlPSb, and any suitable combination thereof. A Group III-V semiconductor compound may further include a Group II element. Examples of a Group III-V semiconductor compound further including a Group II element may include InZnP, InGaZnP, and/or InAlZnP.

Examples of a Group III-VI semiconductor compound may include a two-element compound including GaS, GaSe, GazSes, GaTe, InS, InSe, In₂Se₃, and/or InTe, and a three-element compound including InGaSs and/or InGaSes, and any suitable combination thereof.

Examples of a Group I-III-VI semiconductor compound may include one selected from among a three-element compound including AgInS, AgInS₂, CuInS, CuInS₂, CuGaO₂, AgGaO₂, AgAlO₂, and any suitable combination thereof.

Examples of a Group IV-VI semiconductor compound may include a two-element compound including SnS, SnSe, SnTe, PbS, PbSe, and/or PbTe, a three-element compound including SnSeS, SnSeTe, SnSTe, PbSeS, PbSeTe, PbSTe, SnPbS, SnPbSe, and/or SnPbTe, a four-element compound including SnPbSSe, SnPbSeTe, and/or SnPbSTe, or any suitable combination thereof.

A Group IV element or compound may include one selected from among a single-element including Si and/or Ge, a two-element compound including SiC and/or SiGe, and any suitable combination thereof.

Each element included in a multi-element compound, such as a two-element compound, a three-element compound, and/or a four-element compound, may be present in a particle in a substantially uniform concentration or a substantially non-uniform concentration.

A quantum dot may have a single structure in which the concentration of each element included in the relevant quantum dot is substantially uniform or a double structure of a core-shell. As an example, a material of the core may be substantially different from a material of the shell. The shell of a quantum dot may serve as a protective layer that prevents or reduces a chemical change (e.g., a degree or occurrence of a chemical change) of the core to maintain a semiconductor characteristic and/or serve as a charging layer to give an electrophoretic characteristic to the quantum dot. The shell may include a single layer or a multi-layered structure. An interface between the core and the shell may have a concentration gradient in which the concentration of an element in the shell reduces along a direction toward the center of the shell.

Examples of the shell of the quantum dot may include oxide of metal and/or non-metal, a semiconductor compound, or a combination thereof. Examples of oxides of metals and/or non-metals may include one selected from among a two-element compound including SiO₂, Al₂O₃, TiO₂, ZnO, MnO, Mn₂O₃, Mn₃O₄, CuO, FeO, Fe₂O₃, Fe₃O₄, CoO, Co₃O₄, and/or NiO, and a three-element compound including MgAl₂O₄, CoFe₂O₄, NiFe₂O₄, and/or CoMn₂O₄, and any suitable combination thereof. Examples of the semiconductor compound may include, as described in one or more embodiments, a Group III-VI semiconductor compound, a Group II-VI semiconductor compound, a Group III-V semiconductor compound, a Group I-III-VI semiconductor compound, a Group IV-VI semiconductor compound, and any suitable combination thereof. As an example, the semiconductor compound may include one selected from among CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, and any suitable combination thereof.

A quantum dot may have a full width at half maximum (FWHM) of a light emission wavelength spectrum of about 45 nm or less, for example, about 40 nm or less, and, for example, about 30 nm or less. Within the foregoing ranges, color purity and/or color reproduction may be improved or enhanced. In one or more embodiments, because light emitted from the quantum dot is emitted in all directions, a viewing angle of light may be improved or enhanced.

In one or more embodiments, the shape of the quantum dot may be a spherical (e.g., substantially spherical) shape, a pyramid (e.g., substantially pyramid) shape, a multi-arm (e.g., substantially multi-arm) shape, a cubic (e.g., substantially cubic) shape, a nanoparticle, a nanotube, a nanowire, a nanofiber, a nano plate particle, and/or the like.

Because an energy band gap may be adjusted by adjusting the size of the quantum dot, light in one or more wavelength bands may be obtained from a quantum-dot emission layer. In one or more embodiments, a light-emitting element that emits light in one or more wavelengths may be implemented by utilizing quantum dots of different sizes. For example, the size of the quantum dot may be selected such that red, green, and/or blue light is emitted. In one or more embodiments, the size of the quantum dot may be provided such that light in one or more colors is combined to emit white light.

The first quantum-dot layer 415 may include scatterers (e.g., light scatterers). Because incident light is scattered by scatterers of the first quantum-dot layer 415, the incident light may be efficiently converted by the quantum dots inside the first quantum-dot layer 415. The scatterers may not be particularly limited as long as they are materials that may at least partially scatter transmitted light by providing an optical interface between the scatterers and the light-transmissive resin. For example, the scatterers may be metal oxide particles and/or organic particles. Examples of metal oxides for scatterers may include titanium oxide (TiO₂), zirconium oxide (ZrO₂), aluminum oxide (Al₂O₃), indium oxide (e.g., In₂O₃), zinc oxide (ZnO), and/or tin oxide (SnO₂). Examples of an organic material for the scatters may include an acrylic resin and/or a urethane resin. The scatterers may scatter light in one or more directions regardless of an incident angle while substantially not converting the wavelength of incident light. Through this process, the scatterers may improve or enhance the lateral visibility of the display apparatus. In one or more embodiments, the scatterers of the first quantum-dot layer 415 may increase or enhance a light-converting efficiency by increasing the probability that light incident to the first quantum-dot layer 415 meets the quantum dots.

For a resin used for the first quantum-dot layer 415, any suitable material may be used as long as the material has a high dispersion characteristic for the scatterers and a light-transmissive characteristic. As an example, a polymer resin, such as an acryl-based resin, an imide-based resin, an epoxy-based resin, BCB, and/or HMDSO may be used in providing the first quantum-dot layer 415. The material to provide the first quantum-dot layer 415 may be inside the first hole 501 of the bank 500 that is to overlap the first pixel electrode 311 by inkjet printing.

A second quantum-dot layer 425 may be inside the second hole 502 of the bank 500. If (e.g., when) viewed in the direction (the z-axis direction) perpendicular (e.g., substantially perpendicular) to the upper surface 400a of the first substrate 400, the second quantum-dot layer 425 may be to overlap the second pixel electrode 321. The second quantum-dot layer 425 may be to convert light in the first wavelength band that passes through the second quantum-dot layer 425 into light in a third wavelength band. The third wavelength band may be, for example, in a range from about 495 nm to about 570 nm. However, embodiments of the present disclosure are not limited thereto, and the wavelength band to which a wavelength, for example, a target the second quantum-dot layer 425 converts, belongs, and/or the wavelength band to which a wavelength after the conversion belongs, may be modified to be substantially different.

The second quantum-dot layer 425 may have an arrangement in which quantum dots are dispersed in resin. In one or more embodiments, quantum dots denotes crystals of a semiconductor compound and may include any suitable material that may emit light in one or more wavelength bands depending on the size of the crystals. A diameter of the quantum dots may be, for example, about 1 nm to about 10 nm. Because the description of the quantum dots included in the first quantum-dot layer 415 is applicable to quantum dots included in the second quantum-dot layer 425, description of the quantum dots included in the second quantum-dot layer 425 may be omitted.

The second quantum-dot layer 425 may include scatterers (e.g., light scatterers). Because incident light is scattered by scatterers of the second quantum-dot layer 425, the incident light may be efficiently converted by the quantum dots inside the second quantum-dot layer 425. The scatterers are not particularly limited as long as they are materials that may at least partially scatter transmitted light by providing an optical interface between the scatterers and the light-transmissive resin. For example, the scatterers may be metal oxide particles and/or organic particles. A metal oxide for the scatterers and/or an organic material for the scatterers may be substantially the same as described in one or more embodiments. The scatterers may scatter light in one or more directions regardless of an incident angle while substantially not converting the wavelength of incident light. Through this process, the scatterers may improve or enhance the lateral visibility of the display apparatus. In one or more embodiments, the scatterers of the second quantum-dot layer 425 may increase or enhance a light-converting efficiency by increasing the probability that light incident to the second quantum-dot layer 425 meets the quantum dots.

For a resin used for the second quantum-dot layer 425, any suitable material may be used as long as the material has a high dispersion characteristic for the scatterers and a light-transmissive characteristic. As an example, a polymer resin, such as an acryl-based resin, an imide-based resin, an epoxy-based resin, BCB, and/or HMDSO, may be used to provide the second quantum-dot layer 425. The material to provide the second quantum-dot layer 425 may be inside the second hole 502 of the bank 500 that is to overlap the second pixel electrode 321 by inkjet printing.

The third pixel PX3 may be to emit light of a wavelength in the first wavelength band that is generated from the intermediate layer 303 including the emission layer, to the outside through a plurality of holes without wavelength conversion. In one or more embodiments, the third pixel PX3 may not have a quantum-dot layer. In one or more embodiments, a light-transmissive layer 435 including a light-transmissive resin may be inside the third hole 503 of the bank 500 that is to overlap the third pixel electrode 331. The light-transmissive layer 435 may include acryl, benzocyclobutene (BCB), and/or hexamethyldisiloxane (HMDSO). Besides, the light-transmissive layer 435 may also include scatterers (e.g., light scatterers). In one or more embodiments, the light-transmissive layer 435 may not be inside the third hole 503 of the bank 500.

In one or more embodiments, the first quantum-dot layer 415 and the second quantum-dot layer 425 may be provided by inkjet printing. For example, the bank 500 including the first hole 501, the second hole 502, and the third hole 503 may be on the second inorganic encapsulation layer 630, and then, the first quantum-dot layer 415 and the second quantum-dot layer 425 may be provided by dotting a material to provide the first quantum-dot layer 415 in the first hole 501 using inkjet printing and dotting a material to provide the second quantum-dot layer 425 in the second hole 502 using inkjet printing.

In FIG. 3, a color filter layer may be on the first quantum-dot layer 415, the second quantum-dot layer 425, and the light-transmissive layer 435. For example, a first color filter layer 410 may be on the first quantum-dot layer 415, a second color filter layer 420 may be on the second quantum-dot layer 425, and a third color filter layer 430 may be on the light-transmissive layer 435. The first color filter layer 410 may be to only pass light in a wavelength band of about 630 nm to about 780 nm. The second color filter layer 420 may be to only pass light in a wavelength band of about 450 nm to about 495 nm. The third color filter layer 430 may be to only pass light in a wavelength band of about 495 nm to about 570 nm.

The first color filter layer 410, the second color filter layer 420, and the third color filter layer 430 may enhance the quality of displayed images by enhancing the color purity of light emitted to the outside. In one or more embodiments, the first color filter layer 410, the second color filter layer 420, and the third color filter layer 430 may reduce external light reflection (e.g., a degree or occurrence of external light reflection) by reducing the rate in which external light incident to the display apparatus from the outside is reflected by the first pixel electrode 311, the second pixel electrode 321, and the third pixel electrode 331, and then emitted again to the outside. A black matrix BM may be between the first color filter layer 410, the second color filter layer 420, and the third color filter layer 430.

The first color filter layer 410 may include a hole 421 to expose a first region D1 as illustrated in FIG. 3. The hole 421 may define a region of the first pixel PX1. The first color filter layer 410 may be to fill at least the hole 421. In one or more embodiments, the second color filter layer 420 may include a hole 412 to expose a second region D2 as illustrated in FIG. 3. The hole 412 may define a region of the second pixel PX2. The second color filter layer 420 may be to fill at least the hole 412. An end of the first color filter layer 410 in a direction to the third hole 503 and an end of the second color filter layer 420 in a direction to the third hole 503 may define a hole 423 to expose a third region D3. The hole 423 may define a region of the third pixel PX3.

A portion in which the first color filter layer 410 overlaps the third color filter layer 430, a portion in which the second color filter layer 420 overlaps the third color filter layer 430, and a portion in which the first color filter layer 410 overlaps the second color filter layer 420 may serve as the black matrix BM. As an example, this is because, if (e.g., when) the first color filter layer 410 is provided to pass only light in a wavelength band of about 630 nm to about 780 nm and the third color filter layer 430 is provided to pass only light in a wavelength band of about 450 nm to about 495 nm, there may be no light in a portion where the first color filter layer 410 overlaps the third color filter layer 430 that may pass through both the first color filter layer 410 and the third color filter layer 430, theoretically.

In one or more embodiments, a filler layer 700 may be further provided under the first color filter layer 410, the second color filter layer 420, and/or the third color filter layer 430. The filler layer 700 may be filled with a filler between the bank 500 and the first color filter layer 410, the second color filter layer 420, and/or the third color filter layer 430. The filler may include a light-transmissive material. As an example, the filler may include an acryl-based resin and/or an epoxy-based resin.

In one or more embodiments, if (e.g., when) viewed in the direction (the z axis direction) perpendicular (e.g., substantially perpendicular) to the upper surface 400a of the first substrate 400, a plurality of spacers ELB may be on the pixel-defining layer 150 in a region in which the black matrix BM is provided. For example, if (e.g., when) viewed in the direction (the z axis direction) perpendicular (e.g., substantially perpendicular) to the upper surface 400a of the first substrate 400, the spacers ELB may be in a shape to surround the openings of the pixel-defining layer 150. In one or more embodiments, if (e.g., when) viewed in the direction (the z axis direction) perpendicular (e.g., substantially perpendicular) to the upper surface 400a of the first substrate 400, two or more of the plurality of spacers ELB may be apart from each other.

Referring to FIG. 3, in one or more embodiments, the height of the spacers ELB may be greater than the height of the pixel-defining layer 150. In one or more embodiments, an angle between the lateral side surface of each of the spacers ELB and the upper surface of the pixel-defining layer 150 may be greater than an angle between the lower surface of the pixel-defining layer 150 and the inner side surface of each of the openings of the pixel-defining layer 150. As an example, an angle between the lateral side surface of each of the spacers ELB and the upper surface of the pixel-defining layer 150 may be about 70° to about 90°, and an angle between the lower surface of the pixel-defining layer 150 and the inner side surface of each of the openings of the pixel-defining layer 150 may be about 40° to about 60°. In one or more embodiments, the intermediate layer 303, the opposite electrode 305, and the first inorganic encapsulation layer 610 on the pixel-defining layer 150 may be in a disconnected form without exceeding the height of the spacers ELB.

If (e.g., when) two or more of the spacers ELB are not apart from each other and all of the spacers ELBs are connected to each other, the opposite electrode 305 may be disconnected between the pixels PX and a current may not flow through the opposite electrode 305. In one or more embodiments, the plurality of spacers ELB may be in a region of the black matrix BM, and to prevent the opposite electrode 305 from being disconnected in the display panel 10, two or more of the spacers ELB may be to be apart from each other. Through this process, optical color mixing between the pixels PX may be reduced, and defects of the opposite electrode 305 being disconnected may be prevented from occurring (or a degree of defects of the opposite electrode 305 being disconnected may be reduced).

For example, although it is illustrated in FIG. 3 that the intermediate layer 303, the opposite electrode 305, and the first inorganic encapsulation layer 610 have a disconnected form without exceeding the height of the spacers ELB, such a disconnected form may appear only in a specific cross-sectional view. In one or more embodiments, two or more of the spacers ELB may be apart from each other. In one or more embodiments, in a cross-sectional view of adjacent two pixels, illustrating a region between the spacers ELB, each of the layers other than the emission layer of the intermediate layer 303, the opposite electrode 305, and the first inorganic encapsulation layer 610 may be provided to have a continuous (e.g., substantially continuous) shape in the adjacent two pixels.

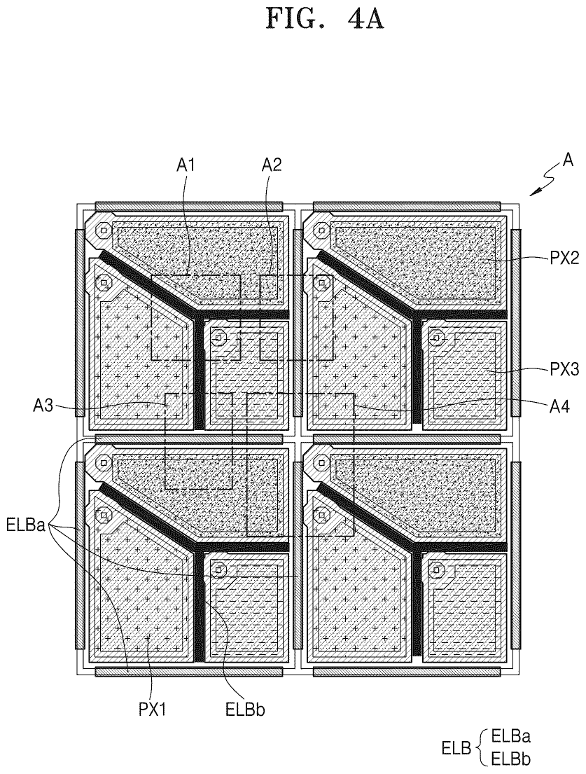

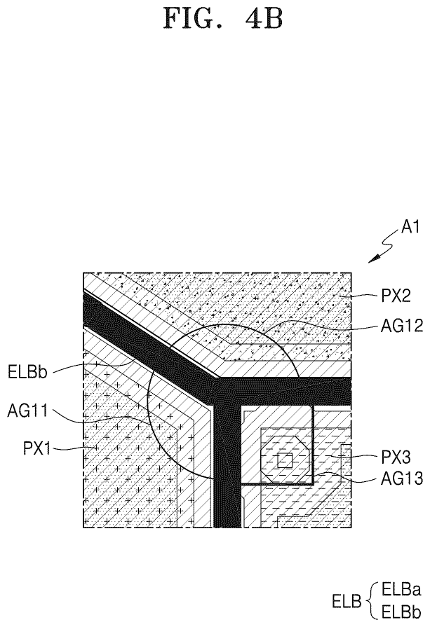

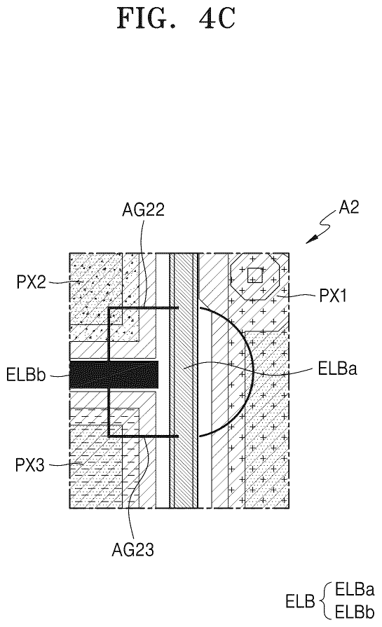

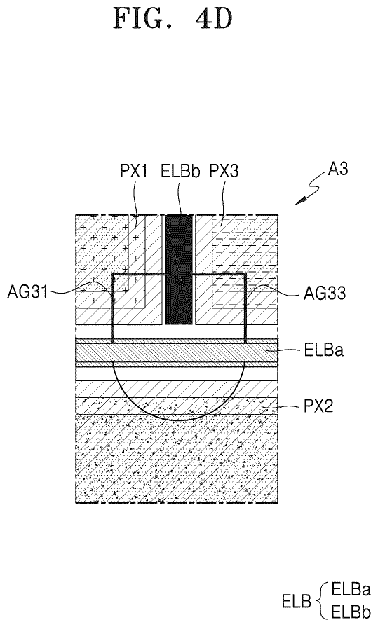

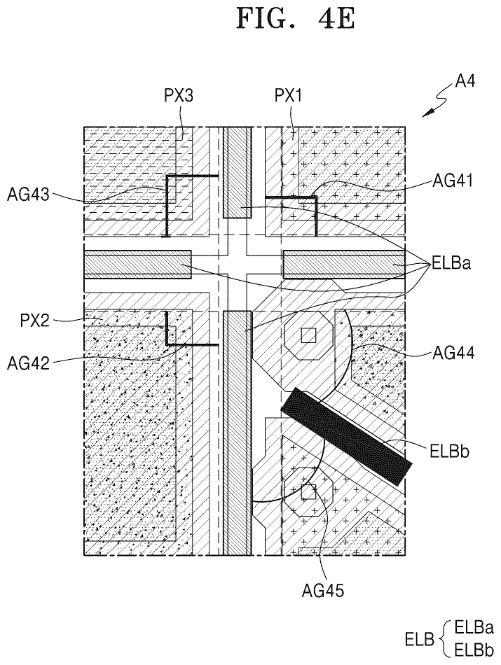

FIG. 4A is a schematic plan view of a portion of a display apparatus according to one or more embodiments, and FIGS. 4B-4E each is an enlarged plan view of a portion of the plan view of FIG. 4A according to one or more embodiments.

Referring to FIG. 4A, the openings of the pixel-defining layer 150 may define regions of the pixels PX1, PX2, and PX3, and each of the openings of the pixel-defining layer 150 may have a polygonal (e.g., substantially polygonal) shape. In one or more embodiments, in the display area DA, a set of pixels in a rectangular (e.g., substantially rectangular) or square (e.g., substantially square) shape, the shapes of which are a combination of the area of the first pixel PX1, the area of the second pixel PX2, and the area of the third pixel PX3, may be provided repeatedly in a row to extend in a first direction (an x axis direction) and/or a column to extend in a second direction (a y axis direction) crossing the first direction. A pixel set of the area of the first pixel PX1, the area of the second pixel PX2, and the area of the third pixel PX3 may correspond to a set of the first pixel electrode 311, the second pixel electrode 321, and the third pixel electrode 331.

If (e.g., when) viewed in the direction (the z axis direction) perpendicular (e.g., substantially perpendicular) to the upper surface 400a of the first substrate 400, the spacers ELB may include first spacers ELBa that is to surround a set of the first pixel electrode 311, the second pixel electrode 321, and the third pixel electrode 331, and second spacers ELBb between the first pixel electrode 311 and the second pixel electrode 321, between the second pixel electrode 321 and the third pixel electrode 331, and between the third pixel electrode 331 and the first pixel electrode 311. In one or more embodiments, the first spacers ELBa may be apart from each other, and the second spacers ELBb may be integrally provided as a single body. The first spacers ELBa and the second spacers ELBb may be to be apart from each other.

Hereinafter, the arrangement structure of the spacers ELB is described in more detail with reference to enlarged plan views of portions of the plan view of FIG. 4A.

Referring to FIG. 4B, a first portion A1 may be a portion in which an angle is formed by the second spacer ELBb which is integrally provided as the single body. In one or more embodiments, an angle between adjacent second spacers among the second spacers ELBb may be about 90° or greater. As an example, an angle AG11 in the area of the first pixel PX1 and an angle AG12 in the area of the second pixel PX2 may exceed about 90°, and an angle AG13 in the area of the third pixel PX3 may be about 90°.

Referring to FIG. 4C, a second portion A2 may be a portion in which an angle between the second spacer ELBb and the first spacer ELBa apart from each other is formed, and referring to FIG. 4D, a third portion A3 may be a portion in which an angle between the second spacer ELBb and the first spacer ELBa apart from each other is formed. In one or more embodiments, at least one selected from among angles formed by each of the second spacers ELBb and an adjacent first spacer among the first spacers ELBa may be about 90° or smaller. As an example, an angle AG22 in the second pixel PX2 and an angle AG23 in the third pixel PX3 in the second portion A2 may be about 90°. In one or more embodiments, an angle AG31 in the first pixel PX1 and an angle AG33 in the third pixel PX3 in the third portion A3 may be about 90°.

Referring to FIG. 4E, a fourth portion A4 may be a portion in which an angle between the first spacers ELBa apart from each other and an angle between the second spacer ELBb and the first spacer ELBa apart from each other are formed. In the fourth portion A4, one angle AG41 of angles in the area of the first pixel PX1, one angle AG42 of angles in the area of the second pixel PX2, and an angle AG43 in the area of the third pixel PX3 may be about 90°, and another angle AG45 of angles in the area of the first pixel PX1 and another angle AG44 of angles in the area of the second pixel PX2 may be about 90° or smaller.

Because a pixel set according to one or more embodiments has an arrangement structure of the spacers ELB described with reference to FIGS. 4B-4E, optical color mixing between the pixels PX may be reduced and an issue that a current may not flow between the pixels PX may be resolved.

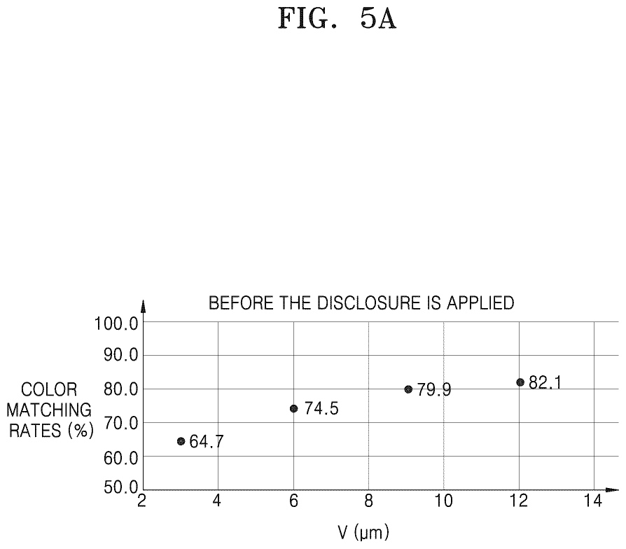

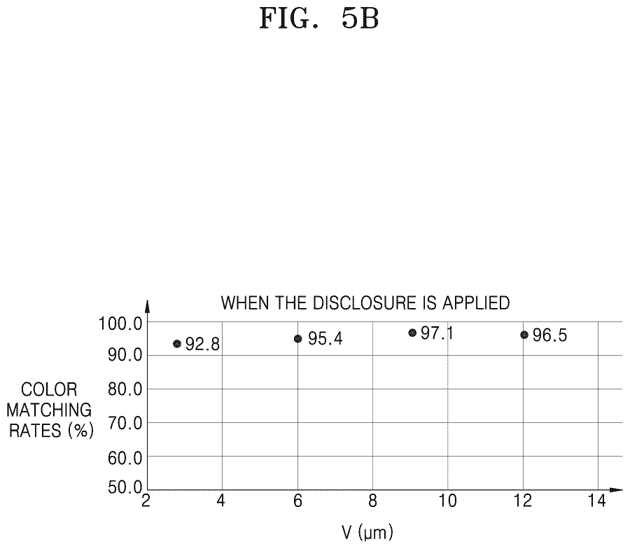

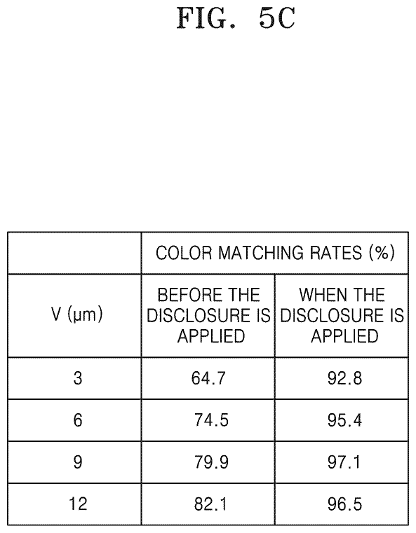

FIGS. 5A-5C each is a graph illustrating experimental results to illustrate an effect according to one or more embodiments.

To reduce power consumption (e.g., a degree or occurrence of power consumption) of a display apparatus, it is desirable for an aperture ratio to be increased. However, if (e.g., when) the aperture ratio is increased, a distance between the pixels PX1, PX2, and PX3 may be reduced, and color matching rates according to optical color mixing may be reduced. In one or more embodiments, there may be a limitation in increasing the aperture. Because a distance V (see FIGS. 2-3) between the opening of the pixel-defining layer 150 and the lateral side surface of the color filter increases, a distance between the pixels PX1, PX2, and PX3 may increase. In one or more embodiments, color matching rates may tend to increase.

Referring to FIGS. 5A-5C, when an aperture ratio is increased before the disclosure is applied, a color matching rate was 64.7% when the distance V is 3 μm, a color matching rate was 74.5% when the distance V is 6 μm, a color matching rate was 79.9% when the distance V is 9 μm, and a color matching rate was 82.1% when the distance V is 12 μm. In contrast, as a result of arranging the spacers ELB according to one or more embodiments, a color matching rate was 92.8% when the distance V is 3 μm, a color matching rate was 95.4% when the distance V is 6 μm, a color matching rate was 97.1% when the distance V is 9 μm, and a color matching rate was 96.5% when V is 12 μm. In one or more embodiments, it was determined that, when the descriptions in one or more embodiments of the present disclosure are applied, color matching rates are improved or enhanced by about 14.4% to about 28.1% and that when a distance V between the opening of the pixel-defining layer 150 and the lateral side surface of the color filter is relatively small, improvement or enhancement rates in the color matching rates are improved or enhanced.

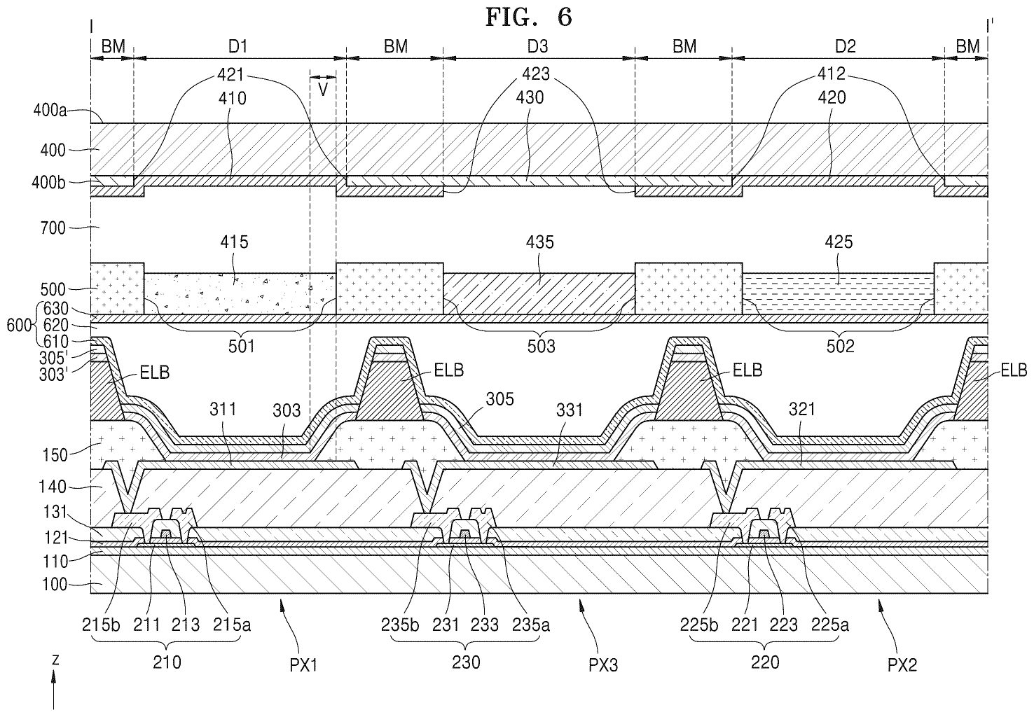

FIG. 6 is a schematic cross-sectional view of a portion of the display apparatus according to one or more embodiments. FIG. 6 is also a cross-sectional view of the display apparatus according to one or more embodiments, taken along line corresponding to line I-I′ of FIG. 2.

In FIG. 6, there may be an additional intermediate layer 303′ and an additional conductive layer 305′ on the upper surface of the spacer ELB. The additional intermediate layer 303′ may include substantially the same material as a material of one or more of the layers included in the intermediate layer 303 on the pixel electrode 311 and may be apart from the intermediate layer 303 on the pixel electrode 311. As an example, if (e.g., when) the intermediate layer 303 includes a hole injection layer, a hole transport layer, an emission layer, and an electron transport layer that are sequentially stacked on the pixel electrode 311, the additional intermediate layer 303′ may include a hole injection layer, a hole transport layer, and an electron transport layer that are sequentially stacked on the upper surface of the spacer ELB. The additional conductive layer 305′ may include substantially the same material as a material of the opposite electrode 305 on the pixel electrode 311 and substantially the same layered structure as a structure of the opposite electrode 305 and may be apart from the opposite electrode 305 on the pixel electrode 311. If (e.g., when) the spacer ELB is sufficiently or suitably sharp, the additional intermediate layer 303′ or the additional conductive layer 305′ may not be on the upper surface of the spacer ELB as illustrated in FIG. 3. In one or more embodiments, if (e.g., when) the width of the spacer ELB is sufficient or suitable, the additional intermediate layer 303′ and the additional conductive layer 305′ may be on the upper surface of the spacer ELB as illustrated in FIG. 6.

In one or more embodiments, the first inorganic encapsulation layer 610 included in the encapsulation layer 600 may cover the lateral side surface of the spacer ELB without being disconnected by the spacer ELB as illustrated in FIG. 6 and have a continuous (e.g., substantially continuous) shape without being disconnected in the display area.

According to one or more embodiments, the display apparatus having improved or enhanced color matching rates, if (e.g., when) implementing a high-resolution product, may be provided.

One or more embodiments of the present disclosure provide an electronic device including the display apparatus as described in one or more embodiments.

In one or more embodiments, the electronic device may be a smartphone, a television, a monitor, a tablet, an electric vehicle, a mobile phone, a tablet personal computer (PC), a mobile communication terminal, an electronic notebook, an electronic book, a portable multimedia player (PMP), a navigation device, an ultra-mobile PC (UMPC), a laptop computer, a billboard, an Internet of Things (IoT) device, a smartwatch, a watch phone, and/or a head-mounted display (HMD).

The aspects and features of embodiments of the present disclosure are not limited to the ones set forth herein. The above and other aspects and features of certain embodiments of the present disclosure will become more apparent to one of ordinary skill in the art to which the present disclosure pertains by referencing the detailed description of the present disclosure.

It should be understood that embodiments described herein should be considered in a descriptive sense only and not for purposes of limitation. Descriptions of features or aspects within each embodiment should typically be considered as available for other similar features or aspects in other embodiments. While the subject matter of the present disclosure has been described with reference to the figures, it will be understood by those of ordinary skill in the art that one or more suitable changes in form and more details may be made therein without departing from the spirit and scope as defined by the following claims and equivalents thereof.

What is claimed is:

1. A display apparatus, comprising:
a substrate;
a first pixel electrode, a second pixel electrode, and a third pixel electrode which are apart from each other and are over the substrate;
a pixel-defining layer comprising openings to expose each of central portions of the first pixel electrode, the second pixel electrode, and the third pixel electrode, wherein the pixel-defining layer is to cover an edge of each of the first pixel electrode, the second pixel electrode, and the third pixel electrode;
spacers over the pixel-defining layer, wherein two or more of the spacers are apart from each other when viewed in a direction perpendicular to the substrate;
a bank comprising holes to correspond to the openings of the pixel-defining layer, wherein the bank is over the spacers;
a first quantum-dot layer in one or more of the holes of the bank; and
a second quantum-dot layer in one or more of the remaining holes of the bank.

2. The display apparatus as claimed in claim 1, wherein, when viewed in the direction perpendicular to the substrate, each of the openings of the pixel-defining layer has a polygonal shape.

3. The display apparatus as claimed in claim 2, wherein, when viewed in the direction perpendicular to the substrate, the spacers are to surround the openings of the pixel-defining layer.

4. The display apparatus as claimed in claim 3, wherein the spacers comprise:
first spacers to surround a set of the first pixel electrode, the second pixel electrode, and the third pixel electrode when viewed in the direction perpendicular to the substrate; and
second spacers between the first pixel electrode and the second pixel electrode, between the second pixel electrode and the third pixel electrode, and between the third pixel electrode and the first pixel electrode when viewed in the direction perpendicular to the substrate.

5. The display apparatus as claimed in claim 4, wherein the second spacers are integrally provided as a single body.

6. The display apparatus as claimed in claim 5, wherein the first spacers are apart from each other.

7. The display apparatus as claimed in claim 6, wherein the first spacers and the second spacers are apart from each other.

8. The display apparatus as claimed in claim 7, wherein an angle between adjacent second spacers among the second spacers is 90° or greater.

9. The display apparatus as claimed in claim 8, wherein at least one selected from among angles between each of the second spacers and an adjacent spacer among the first spacers is 90° or smaller.

10. The display apparatus as claimed in claim 9, wherein a height of each of the spacers is greater than a height of the pixel-defining layer.

11. The display apparatus as claimed in claim 9, wherein an angle between a lateral side surface of each of the spacers and an upper surface of the pixel-defining layer is greater than an angle between a lower surface of the pixel-defining layer and an inner side surface of each of the openings.

12. The display apparatus as claimed in claim 10, wherein the spacers comprise a black dye.

13. A method of manufacturing a display apparatus, the method comprising:
providing a substrate;
providing a first pixel electrode, a second pixel electrode, and a third pixel electrode which are apart from each other and are over the substrate;
providing a pixel-defining layer comprising openings to expose each of central portions of the first pixel electrode, the second pixel electrode, and the third pixel electrode, wherein the pixel-defining layer is to cover an edge of each of the first pixel electrode, the second pixel electrode, and the third pixel electrode;
providing spacers over the pixel-defining layer, wherein two or more of the spacers are apart from each other when viewed in a direction perpendicular to the substrate;
providing a bank comprising holes to correspond to the openings of the pixel-defining layer, wherein the bank is over the spacers;
providing a first quantum-dot layer in one or more of the holes of the bank; and
providing a second quantum-dot layer in one or more of the remaining holes of the bank.

14. The method as claimed in claim 13, wherein the providing of the pixel-defining layer comprises, when viewed in the direction perpendicular to the substrate, providing the pixel-defining layer in which each of the openings has a polygonal shape.

15. The method as claimed in claim 14, wherein the providing of the spacers comprises, when viewed in the direction perpendicular to the substrate, providing the spacers to surround the openings of the pixel-defining layer.

16. The method as claimed in claim 15, wherein the providing of the spacers comprises:
providing first spacers to surround a set of the first pixel electrode, the second pixel electrode, and the third pixel electrode when viewed in the direction perpendicular to the substrate; and
providing second spacers between the first pixel electrode and the second pixel electrode, between the second pixel electrode and the third pixel electrode, and between the third pixel electrode and the first pixel electrode when viewed in the direction perpendicular to the substrate.

17. The method as claimed in claim 16, wherein the providing of the second spacers comprises providing second spacers integrally as a single body.

18. The method as claimed in claim 17, wherein the providing of the second spacers comprises providing first spacers apart from each other.

19. The method as claimed in claim 18, wherein the providing of the second spacers comprises providing second spacers in which an angle between adjacent second spacers among the second spacers is 90° or greater.

20. The method as claimed in claim 19, wherein the providing of the spacers comprises providing spacers in which at least one selected from among angles between each of the second spacers and an adjacent spacer among the first spacers is 90° or smaller.

21. An electronic device, comprising:
display apparatus comprising:
a substrate;
a first pixel electrode, a second pixel electrode, and a third pixel electrode which are apart from each other and are over the substrate;
a pixel-defining layer comprising openings to expose each of central portions of the first pixel electrode, the second pixel electrode, and the third pixel electrode, wherein the pixel-defining layer is to cover an edge of each of the first pixel electrode, the second pixel electrode, and the third pixel electrode;
spacers over the pixel-defining layer, wherein two or more of the spacers are apart from each other when viewed in a direction perpendicular to the substrate;
a bank comprising holes to correspond to the openings of the pixel-defining layer, wherein the bank is over the spacers;
a first quantum-dot layer in one or more of the holes of the bank; and
a second quantum-dot layer in one or more of the remaining holes of the bank.

22. The electronic device as claimed in claim 21, wherein the electronic device is a smartphone, a television, a monitor, a tablet, an electric vehicle, a mobile phone, a tablet personal computer (PC), a mobile communication terminal, an electronic notebook, an electronic book, a portable multimedia player (PMP), a navigation device, an ultra-mobile PC (UMPC), a laptop computer, a billboard, an Internet of Things (IoT) device, a smartwatch, a watch phone, or a head-mounted display (HMD).
